(19) United States
(12) Patent Application Publication
(10) Pub. No.: US 2014/0184288 A1
(43) Pub. Date: Jul. 3, 2014

(54) SEMICONDUCTOR CIRCUIT AND METHOD FOR OPERATING THE SAME

(71) Applicant: Samsung Electronics Co., Ltd., Suwon-si (KR)

(72) Inventors: Chung-Hee KIM, Yongin-si (KR); Ju-Hyun KANG, Hwaseong-si (KR); Dong-Youb KIM, Hwaseong-si (KR); Min-su KIM, Hwaseong-si (KR); Sun-Gyeum KIM, Goyang-si (KR); Uk-Rae CHO, Suwon-si (KR); Sang-Shin HAN, Suwon-si (KR)

(73) Assignee: Samsung Electronics Co., Ltd., Suwon-si (KR)

(21) Appl. No.: 14/132,111

(22) Filed: Dec. 18, 2013

Related U.S. Application Data
(60) Provisional application No. 61/746,270, filed on Dec. 27, 2012.

(30) Foreign Application Priority Data
Mar. 15, 2013 (KR) 10-2013-0028177

(51) Int. Cl. H03L 7/00

(52) U.S. Cl. CPC H03L 7/00
USPC 327/153

(57) ABSTRACT

Provided are a semiconductor circuit and method for operating the same. The semiconductor circuit includes a first flip-flop configured to, based on input data synchronized to a first clock, output first output data synchronized to a second clock different from the first clock, and a second flip-flop configured to, based on the first output data, output second output data synchronized to the second clock, wherein the first and the second flip-flops share an inverted second clock and a delayed second clock and output the first and the second output data based thereon, respectively.

### CROSS-REFERENCE TO RELATED APPLICATION

This application claims priority from U.S. Provisional Application No. 61/746,270, filed on Dec. 27, 2012, and Korean Patent Application No. 10-2013-0028177, filed on Mar. 15, 2013, in the Korean Intellectual Property Office, the disclosures of which are incorporated herein in their entireties by reference.

### BACKGROUND

1. Field

Apparatuses and methods consistent with exemplary embodiments relate to a semiconductor circuit and a method for operating the same.

2. Description of the Related Art

With a trend toward miniaturized electronic products, a variety of system on chip (SoC) products in which multi-functional chips are packaged into a single package are released in the market. Since various chips included in the SoC product performs different functions, data are processed in different clock domains and the processed data are then exchanged according to a need.

When the data processed in different clock domains are exchanged, it is important that data are exchanged without data loss to ensure reliability of product operation.

### SUMMARY

One or more exemplary embodiments provide a semiconductor circuit having improved operational reliability.

One or more exemplary embodiments also provide a method for operating a semiconductor circuit having improved operational reliability.

According to an aspect of an exemplary embodiment, there is provided a semiconductor circuit including a first flip-flop configured to, based on input data synchronized to a first clock, output first output data synchronized to a second clock different from the first clock, and a second flip-flop configured to, based on the first output data, output second output data synchronized to the second clock, wherein the first and the second flip-flops share an inverted second clock and a delayed second clock and output the first and the second output data based thereon, respectively.

According to an aspect of another exemplary embodiment, there is provided a method for operating a semiconductor circuit, the method including generating an inverted second clock and a delayed second clock from a second clock, receiving input data synchronized to a first clock different from the second clock, outputting first output data synchronized to the second clock based on the input data, and outputting second output data synchronized to the second clock based on the first output data, wherein the outputting the first output data and the outputting the second output data are performed based on a shared inverted second clock and a shared delayed second clock.

According to an aspect of still another exemplary embodiment, there is provided a semiconductor circuit including: a plurality of flip-flops comprising a first through an n-th flip-flops connected to one another in series. The first flip-flop may output data synchronized to a second clock based on input data synchronized to a first clock different from the second clock, an inverted second clock, and a delayed second clock. Each of a second through the n-th flip-flops may output data synchronized to the second clock based on input data from an adjacent flip-flop, the inverted second clock, and the delayed second clock. At least one of the inverted second clock and the delayed second dock may be shared among at least a portion of the first through the n-th flip-flops.

### BRIEF DESCRIPTION OF THE DRAWINGS

The above and/or other aspects will become more apparent by describing in detail certain exemplary embodiments with reference to the accompanying drawings in which:

FIG. 1 is a block diagram of a semiconductor circuit according to an exemplary embodiment;

FIG. 2 is a circuit diagram of a flip-flop shown in FIG. 1;

FIG. 3A is a timing diagram for explaining a method for operating a semiconductor circuit according to an exemplary embodiment;

FIG. 3B is a flowchart illustrating a semiconductor circuit simulation method using a semiconductor circuit according to an exemplary embodiment;

FIG. 4 is a circuit diagram of a semiconductor circuit according to another exemplary embodiment;

FIG. 5 is a block diagram of a semiconductor circuit according to still another exemplary embodiment;

FIG. 6 is a block diagram of a semiconductor circuit according to still another exemplary embodiment;

FIG. 7 is a block diagram of a semiconductor circuit according to still another exemplary embodiment;

FIG. 8 is a block diagram of an electronic system to which a semiconductor circuit according to exemplary embodiments may be employed;

FIG. 9 illustrates an example in which the electronic system shown in FIG. 8 is applied to a smart phone;

FIG. 10 illustrates an example in which the electronic system shown in FIG. 8 is applied to a tablet PC; and

FIG. 11 illustrates an example in which the electronic system shown in FIG. 8 is applied to a notebook computer.

### DETAILED DESCRIPTION

Certain exemplary embodiments are described in greater detail below with reference to the accompanying drawings. The exemplary embodiments may, however, be embodied in various different forms and should not be construed as being limited to the exemplary embodiments set forth herein. Rather, these exemplary embodiments are provided so that this disclosure will be thorough and complete and will fully convey the concept of the disclosure to those skilled in the art. In the drawings, the thickness of layers and regions are exaggerated for clarity.

It will be understood that when an element or layer is referred to as being “on” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

The use of the terms “a” and “an” and “the” and similar referents in the context of describing the disclosure (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the disclosure.

Unless defined otherwise, all technical and scientific terms used herein have the same meaning as commonly understood by one of ordinary skill in the art to which the disclosure belongs. It is noted that the use of any and all examples, or exemplary terms provided herein is intended merely to better illuminate the disclosure and is not a limitation on the scope of the disclosure unless otherwise specified. Further, unless defined otherwise, all terms defined in generally used dictionaries may not be overly interpreted.

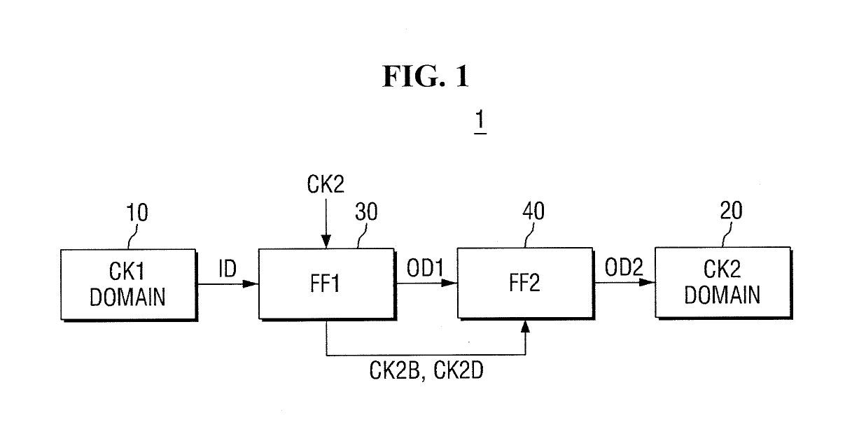

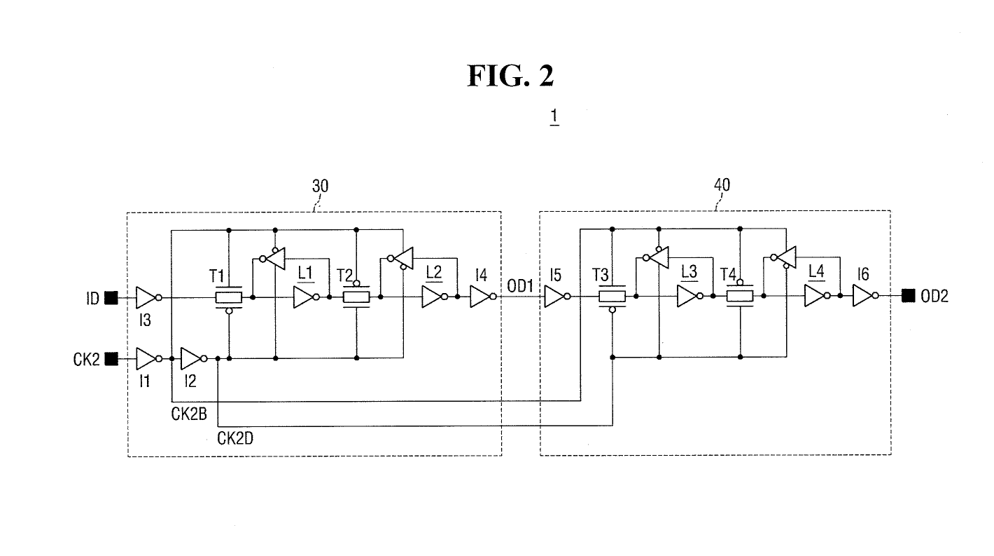

Hereinafter, a semiconductor circuit according to an exemplary embodiment will be described with reference to FIGS. 1 and 2. In the following description, the semiconductor circuit will be described with regard to a synchronizer by way of example, but exemplary embodiments are not limited thereto.

FIG. 1 is a block diagram of a semiconductor circuit according to an exemplary embodiment and FIG. 2 is a circuit diagram of a flip-flop shown in FIG. 1.

Referring to FIGS. 1 and 2, a semiconductor circuit 1 includes a first flip-flop 30 and a second flip-flop 40.

The first flip-flop 30 may receive input data ID from a first clock domain 10. Here, the first clock domain 10 may be a domain in which circuits or elements for processing data are synchronized to a first clock CK1. Therefore, the input data ID output from the first clock domain 10 may be synchronized to the first clock CK1.

The first flip-flop 30 may receive a second clock CK2 different from the first clock CK1. In an exemplary embodiment, the first clock CK1 and the second clock CK2 may be different from each other. In detail, the first clock CK1 and the second clock CK2 may have different clock cycles.

The first flip-flop 30 may receive the input data ID synchronized to the first clock CK1 from the first clock domain 10 and may output the received the input data ID as first output data OD1 synchronized to the second clock CK2. To perform the above-described operation, as shown in FIG. 2, the first flip-flop 30 may include a first latch L1 and a second latch L2. In an exemplary embodiment, the first latch L1 may be a master latch and the second latch L2 may be a slave latch, but exemplary embodiments are not limited thereto.

In detail, the first flip-flop 30 may include, for example, first to fourth inverters I1 to I4, first and second transfer gates T1 and T2, and first and second latches L1 and L2.

The first transfer gate T1 is controlled by an inverted second clock CK2B and a delayed second clock CK2D provided to a first and a second terminals thereof, respectively, and may determine whether to transmit the input data ID. In detail, the inverted second clock CK2B inverted by a first inverter I1 may be provided to the first terminal of the first transfer gate T1. The delayed second clock CK2D delayed by a second inverter I2 connected to the first inverter I1 in series may be provided to the second terminal of the first transfer gate T1. The input data ID may be inverted by a third inverter I3 to be provided to the first transfer gate T1.

The first latch L1 may latch the input data ID received from the first transfer gate T1. More specific operations of the first transfer gate T1 and the first latch L1 will later be described.

The second transfer gate T2 and the second latch L2 may have configurations substantially similar to those of the first transfer gate T1 and the first latch L1, respectively. That is, the second transfer gate T2 is controlled by the inverted second clock CK2B and the delayed second clock CK2D provided to a first and a second terminal thereof, respectively, and may determine whether to transmit the input data ID received from the first latch L1. However, the second transfer gate T2 and the second latch L2 may operate at different clock timings compared to the first transfer gate T1 and the first latch L1, which will later be described in more detail.

The inverted input data ID output from the second latch L2 may further be inverted by a fourth inverter I4. That is, the input data ID is latched by the first and second latches L1 and L2 while the input data ID is inverted by the third inverter I3 and is further inverted by the fourth inverter I4. Therefore, when the input data ID is output from the first flip-flop 30, the input data ID is restored to its original state. The input data ID output from the first flip-flop 30 is provided to the second flip-flop 40 as the first output data OD1.

The second flip-flop 40 receives the first output data OD1 from the first flip-flop 30 and outputs the received first output data OD1 as the second output data OD2. In an exemplary embodiment, the first output data OD1 output from the first flip-flop 30 and the second output data OD2 output from the second flip-flop 40 may be synchronized to the second clock CK2. In such a manner, the second output data OD2 synchronized to the second clock CK2 may be provided to a second clock domain 20. Here, the second clock domain 20 may mean a domain in which circuit or elements for processing data are synchronized to the second clock CK2.

In an exemplary embodiment, o output the second output data OD2 synchronized to the second clock CK2, unlike the first output data OD1 output from the first flip-flop 30, the second flip-flop 40 may not receive the second clock CK2 but may receive the inverted second clock CK2B and the delayed second clock CK2D from the first flip-flop 30. In other words, in an exemplary embodiment, the first flip-flop 30 and the second flip-flop 40 may share the inverted second clock CK2B and the delayed second clock CK2D and may output the first output data OD1 and the second output data OD2, respectively.

In detail, the second flip-flop 40 may include, for example, fifth and sixth inverters I5 and I6, third and fourth transfer gates T3 and T4 and third and fourth latches L3 and L4. In an exemplary embodiment, the third latch L3 may be a master latch and the fourth latch L4 may be a slave latch, but exemplary embodiments are not limited thereto.

The inverted second clock CK2B inverted by the first inverter I1 of the first flip-flop 30 may be provided to a first terminal of the third transfer gate T3 of the second flip-flop 40. In addition, the delayed second clock CK2D delayed by the second inverter I2 of the first flip-flop 30 may be provided to a second terminal of the third transfer gate T3. The first output data OD1 output from the first flip-flop 30 may be inverted by a fifth inverter I5 and provided to the third transfer gate T3.

The third latch L3 may latch the first output data OD1 received from the third transfer gate T3. More specific operations of the third transfer gate T3 and the third latch L3 will later be described.

The fourth transfer gate T4 and the fourth latch L4 may have substantially the same configurations with those of the second transfer gate T2 and the second latch L2 of the first flip-flop 30, respectively.

The inverted first output data OD1 output from the fourth latch L4 may further be inverted by a sixth inverter I6. That is, the first output data OD1 provided from the first flip-flop 30 is latched by the third and fourth latches L3 and L4 while the first output data OD1 is inverted by the fifth inverter I5 and is further inverted by the sixth inverter I6. Therefore, when the first output data OD1 is output, the first output data OD1 is restored to its original state. The first output data OD1 output from the second flip-flop 40 is provided to the second clock domain 20 as the second output data OD2.

Although not shown in detail, additional circuits may further be provided between the first flip-flop 30 and the second flip-flop 40 according to a need. That is, the first output data OD1 output from the first flip-flop 30 may be processed by a predetermined circuit to be provided to the second flip-flop 40. Further, other circuits may further be provided between the first latch L1 and the second latch L2 and between the third latch L3 and the fourth latch L4 according to a need.

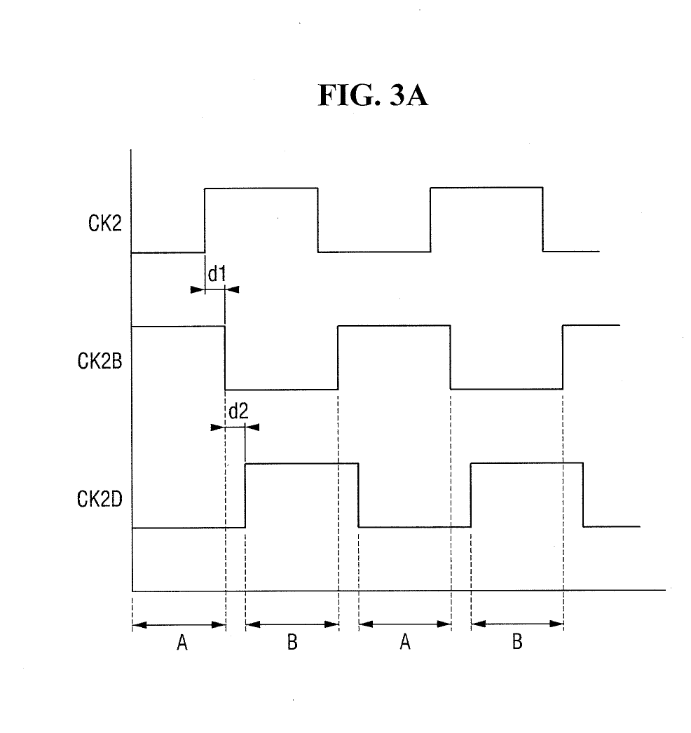

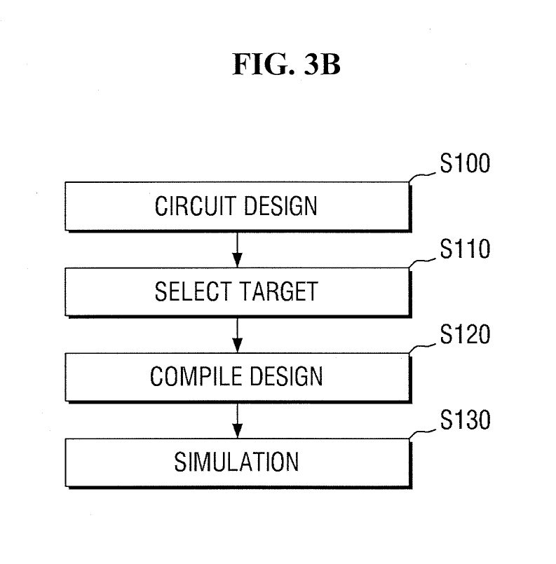

Hereinafter, a method for operating a semiconductor circuit according to an exemplary embodiment will be described with reference to FIGS. 2 and 3A.

FIG. 3A is a timing diagram for explaining a method for operating a semiconductor circuit according to an exemplary embodiment.

Referring to FIGS. 2 and 3A, when the second clock CK2 is changed from a second level (e.g., logical low level) to a first level (e.g., logical high level), the inverted second clock CK2B may be changed from the first level (e.g., logical high level) to the second level (e.g., logical low level). Here, as shown in FIG. 3A, a first delay d1 may be generated between the second clock CK2 and the inverted second clock CK2B by the first inverter I1. When the inverted second clock CK2B is changed from the first level (e.g., logical high level) to the second level (e.g., logical low level), the delayed second clock CK2D may be changed from the second level (e.g., logical low level) to the first level (e.g., logical high level). Here, as shown in FIG. 3A, a second delay d2 may be generated between the inverted second clock CK2B and the delayed second clock CK2D.

In a section A in which the inverted second clock CK2B is at the first level (e.g., logical high level) and the delayed second clock CK2D is at the second level (e.g., logical low level), the first transfer gate T1 and the third transfer gate T3 are turned on to allow the first latch L1 and the third latch L3 to perform latching operations. Here, the second transfer gate T2 and the fourth transfer gate T4 are turned off, and thus the second latch L2 and the fourth latch L4 may not perform latching operations.

In detail, in the section A, when the first transfer gate T1 is turned on, the input data ID is stored in the first latch L1, and when the third transfer gate T3 is turned on, the first output data OD1 output from the second latch L2 may be stored in the third latch L3. When the second and fourth transfer gates T2 and T4 are turned off, the second latch L2 and the fourth latch L4 may retain previously stored data without receiving new data.

Next, in a section B in which the inverted second clock CK2B is at the second level (e.g., logical low level) and the delayed second clock CK2D is at the first level (e.g., logical high level), the second transfer gate T2 and the fourth transfer gate T4 are turned on to allow the second latch L2 and the fourth latch L4 to perform latching operations. Here, the first transfer gate T1 and the third transfer gate T3 may be turned off so that the first latch L1 and the third latch L3 may not perform latching operations.

In detail, in the section B, when the second transfer gate T2 is turned on, the input data ID stored in the first latch L1 may be stored in the second latch L2, and when the fourth transfer gate T4 is turned on, the first output data OD1 stored in the third latch L3 may be stored in the fourth latch L4. The first and third transfer gates T1 and T3 are turned off, and thus the first latch L1 and the third latch L3 may retain previously stored data without receiving new data.

In the semiconductor circuit 1 according to an exemplary embodiment, through the above-described operations, the input data ID synchronized to the first clock CK1 received from the first clock domain 10 may be converted into the second output data OD2 synchronized to the second clock CK2 to be transmitted to the second clock domain 20. Here, in an exemplary embodiment, the inverted second clock CK2B and the delayed second clock CK2D generated from the first flip-flop 30 are shared by the first flip-flop 30 and the second flip-flop 40. Therefore, operational reliability of the semiconductor circuit 1 may be improved, which will now be described in more detail.

For example, in a related art, the inverted second clock CK2B and the delayed second clock CK2D are not shared by the first flip-flop 30 and the second flip-flop 40, unlike the semiconductor circuit 1 according to an exemplary embodiment. That is, for example, similar to the first flip-flop 30, the second flip-flop 40 also receives the second clock CK2 and generates the inverted second clock CK2B and the delayed second clock CK2D by using inverters (not shown) included therein. In this case, when the first and second inverters I1 and I2 of the first flip-flop 30 and the inverters (not shown) of the second flip-flop 40 have different characteristics due to a process variation, etc., timings of the inverted second clock CK2B and the delayed second clock CK2D, generated from the first flip-flop 30, and timings of the inverted second clock CK2B and the delayed second clock CK2D, generated from the second flip-flop 40, may be different from each other. A discrepancy between the clock timings of the first and second flip-flops 30 and 40 may adversely affect operational reliability of a semiconductor circuit.

In the semiconductor circuit 1 according to an exemplary embodiment, since the inverted second clock CK2B and the delayed second clock CK2D, generated from the first flip-flop 30, are shared by the first flip-flop 30 and the second flip-flop 40, a discrepancy may not occur between the clock timings of the first and second flip-flops 30 and 40. Accordingly, the operational reliability of the semiconductor circuit 1 may be improved.

In the semiconductor circuit 1 according to an exemplary embodiment, the first flip-flop 30 and the second flip-flop 40 may be designed as a single sync cell to be provided as a standard cell to a design library. That is, a pair of the first flip-flop 30 and the second flip-flop 40 may be set as a design constraint when a designer designs a circuit using, for example, a hardware description language (HDL). In such a way, synchronization between flip-flops, which may occur during circuit design, may be more reliable.

Hereinafter, a semiconductor circuit simulation method using a semiconductor circuit according to an exemplary embodiment will be described with reference to FIG. 3B in more detail.

FIG. 3B is a flowchart illustrating a semiconductor circuit simulation method using a semiconductor circuit according to an exemplary embodiment.

Referring to FIG. 3B, a circuit is designed (S100). Here, the circuit may be designed by describing functional blocks by using, for example, a hardware description language (HDL).

Next, a target block is selected from the designed functional blocks (S110). When, among the designed functional blocks, a block intended to use the aforementioned sync cell comprising the pair of the first flip-flop 30 and the second flip-flop 40 is selected as the target block, a design constraint for defining the sync cell is inserted into the target block.

Next, the design is compiled (S120). A circuit suited to the inserted design constraint may be compiled using a design compiler.

Next, simulation is performed (S130). A standard cell library is linked to the compiled circuit to perform, for example, timing simulation, and the simulation result is verified.

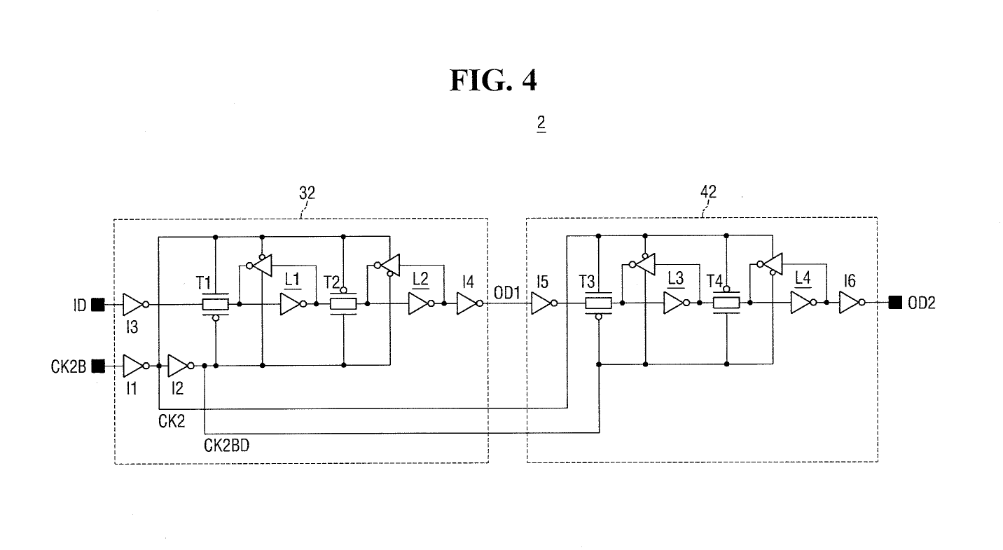

FIG. 4 is a circuit diagram of a semiconductor circuit according to another exemplary embodiment. For brevity, repeated descriptions of the same details as those of the previous exemplary embodiment will be omitted, and the following description will focus on differences between the present and previous exemplary embodiments.

Referring to FIG. 4, a semiconductor circuit 2 includes a first flip-flop 32 and a second flip-flop 42. An inverted second clock CK2B is provided to the first flip-flop 32. That is, unlike the previous exemplary embodiment in which the second clock CK2 is provided to the first flip-flop (30 of FIG. 2) and the inverted second clock CK2B and the delayed second clock CK2D are generated from the first flip-flop (30 of FIG. 2), in this exemplary embodiment, the inverted second clock CK2B is provided to the first flip-flop 32 and a second clock CK2 and a delayed inverted second clock CK2BD are generated from the first flip-flop 32.

The second clock CK2 and the delayed inverted second clock CK2BD, generated from the first flip-flop 32, are shared by the first flip-flop 32 and the second flip-flop 42. That is, the second flip-flop 42 may perform a latching operation using the second clock CK2 and the delayed inverted second clock CK2BD received from the first flip-flop 32.

In this case, the first flip-flop 32 and the second flip-flop 42 may operate at different clock timings from those shown in FIG. 3A.

For example, when the second clock CK2 is at a first level (e.g., logical high level) and the delayed inverted second clock CK2BD is at a second level (e.g., logical low level), a first transfer gate T1 and a third transfer gate T3 may be turned on to allow a first latch L1 and a third latch L3 to perform latching operations. Here, a second transfer gate T2 and a fourth transfer gate T4 may be turned off so that a second latch L2 and a fourth latch L4 may not perform latching operations.

Next, when the second clock CK2 is at the second level (e.g., logical low level) and the delayed inverted second clock CK2BD is at the first level (e.g., logical high level), the second transfer gate T2 and the fourth transfer gate T4 may be turned on to allow the second latch L2 and the fourth latch L4 to perform latching operations. Here, the first transfer gate T1 and the third transfer gate T3 may be turned off so that the first latch L1 and the third latch L3 may not perform latching operations.

As described above, in the semiconductor circuit 2 according to an exemplary embodiment, since the second clock CK2 and the delayed inverted second clock CK2BD are shared by the first flip-flop 32 and the second flip-flop 42, operational reliability of the semiconductor circuit 2 may be improved.

In the semiconductor circuit 2 according to an exemplary embodiment, the first flip-flop 32 and the second flip-flop 42 may be designed as a single sync cell to be provided as a standard cell to a design library.

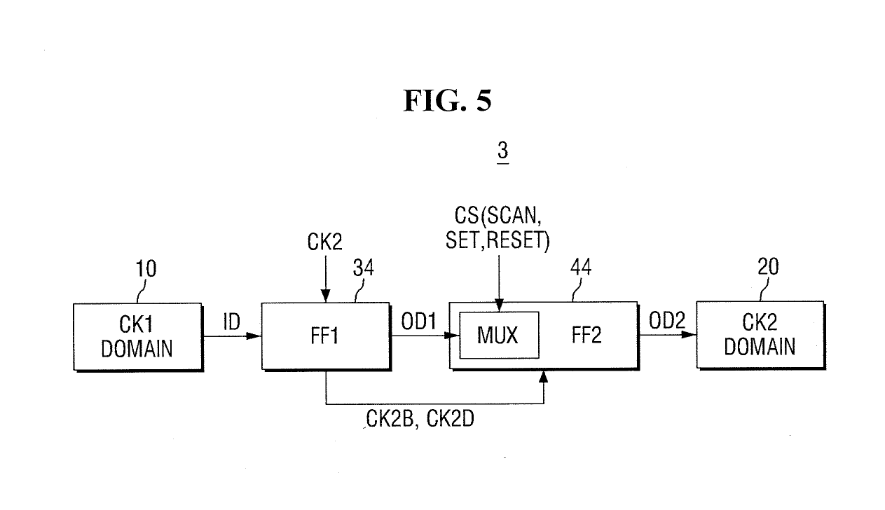

FIG. 5 is a block diagram of a semiconductor circuit according to still another exemplary embodiment. For brevity, repeated descriptions of the same details as those of the previous exemplary embodiment will be omitted, and the following description will focus on differences between the present and previous exemplary embodiments.

Referring to FIG. 5, a semiconductor circuit 3 includes a first flip-flop 34 and a second flip-flop 44. The second flip-flop 44 may include a multiplexer MUX that selects one of first output data OD1 and a control signal CS. That is, one of the first output data OD1 and the control signal CS may be selected to be input to the second flip-flop 44 under control of the multiplexer MUX.

In exemplary embodiments, examples of the control signal CS provided to the second flip-flop 44 may include a scan signal (SCAN), a set signal (SET), and a reset signal (RESET). When the scan signal SCAN is provided to the second flip-flop 44, the second flip-flop 44 may perform a scanning operation. In addition, when the set signal SET, or the reset signal RESET is provided to the second flip-flop 44, the second flip-flop 44 may output predetermined set data or reset data in response thereto. In the above, the scan signal SCAN, the set signal SET, and the reset signal RESET have been described as the examples of the control signal CS provided to the second flip-flop 44, but exemplary embodiments are not limited thereto.

The multiplexer MUX is shown to be included only in the second flip-flop 44 in FIG. 5, but exemplary embodiments are not limited thereto. In an alternative embodiment, the multiplexer MUX may also be included in the first flip-flop 34. In addition, in another alternative embodiment, the multiplexer MUX may be included only in the first flip-flop 34. In addition, in the semiconductor circuit 3 according to an exemplary embodiment, the first flip-flop 34 and the second flip-flop 44 may be designed as a single sync cell to be provided as a standard cell to a design library.

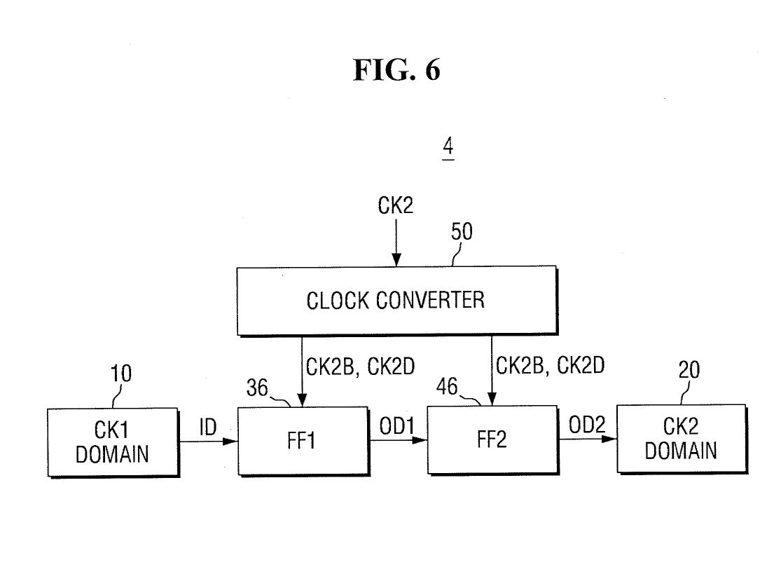

FIG. 6 is a block diagram of a semiconductor circuit according to still another exemplary embodiment. For brevity, repeated descriptions of the same details as those of the previous exemplary embodiment will be omitted, and the following description will focus on differences between the present and previous exemplary embodiments.

In the following description, the term “unit” or “module” as used herein means, but is not limited to, a software or hardware component, such as a Field Programmable Gate Array (FPGA) or an Application Specific Integrated Circuit (ASIC), which performs certain tasks. A module may be configured to reside on the addressable storage medium and configured to execute on one or more processors. Thus, a module may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables. The functionality provided for in the components and modules may be combined into fewer components and modules or further separated into additional components and modules.

Referring to FIG. 6, a semiconductor circuit 4 may further include a clock converter 50. The clock converter 50 may receive a second clock CK2 and may generate an inverted second clock CK2B and a delayed second clock CK2D based on the received second clock CK2. In addition, the clock converter 50 may provide the inverted second clock CK2B and the delayed second clock CK2D to the first flip-flop 36 and the second flip-flop 46. Therefore, similar to the previous exemplary embodiments, the inverted second clock CK2B and the delayed second clock CK2D provided by the clock converter 50 may be shared by the first flip-flop 36 and the second flip-flop 46. In other words, the first flip-flop 36 and the second flip-flop 46 may be modified to have a configuration of the second flip-flop 40 shown in FIG. 2 or the second flip-flop 42 shown in FIG. 4.

In an exemplary embodiment, to generate the inverted second clock CK2B and the delayed second clock CK2D based on the second clock CK2, the clock converter 50 may include, for example, a plurality of inverters (not shown), but exemplary embodiments are not limited thereto. That is, the configuration of the clock converter 50 may be modified in various manners according to a need. In addition, in the semiconductor circuit 4 according to an exemplary embodiment, the first flip-flop 36 and the second flip-flop 46 may be designed as a single sync cell to be provided as a standard cell to a design library.

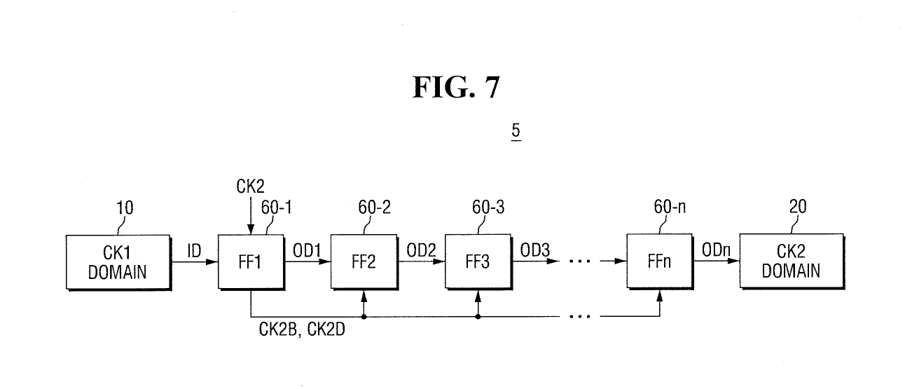

FIG. 7 is a block diagram of a semiconductor circuit according to still another exemplary embodiment. For brevity, repeated descriptions of the same details as those of the previous exemplary embodiment will be omitted, and the following description will focus on differences between the present and previous exemplary embodiments.

Referring to FIG. 7, a semiconductor circuit 5 may include a plurality of flip-flops 60-1 to 60-n. A first flip-flop 60-1 may receive input data ID from a first clock domain 10 and may output the received input data ID as first output data OD1 synchronized to a second clock CK2. The second flip-flop 60-2 may receive the first output data OD1 from the first flip-flop 60-1 and may output the received first output data OD1 as second output data OD2 synchronized to the second clock CK2. The third flip-flop 60-3 may receive the second output data OD2 from the second flip-flop 60-2 and may output the received second output data OD2 as third output data OD3 synchronized to the second clock CK2. The above-described operations are repeatedly performed, and the last flip-flop, i.e., an n-th flip-flop 60-n, may receive (n−1)-th output data OD(n−1) from the (n−1)-th flip-flop 60-(n−1) and outputs the received (n−1)-th output data OD(n−1) as n-th output data ODn synchronized to the second clock CK2. The n-th output data ODn are transmitted to a second clock domain 20.

The first flip-flop 60-1 may receive the second clock CK2 and may generate an inverted second clock CK2B and a delayed second clock CK2D based on the received second clock CK2 to provide the inverted second clock CK2B and the delayed second clock CK2D to the second to n-th flip-flops 60-2 to 60-n, as shown in FIG. 7. Therefore, the first to n-th flip-flops 60-1 to 60-n may share the inverted second clock CK2B and the delayed second clock CK2D.

In this exemplary embodiment shown in FIG. 7, the first flip-flop 60-1 receives the second clock CK2 and generates the inverted second clock CK2B and the delayed second clock CK2D based on the received second clock CK2, but exemplary embodiments are not limited thereto. In an alternative embodiment, the semiconductor circuit 5 may be modified to include a clock converter (not shown) that receives the second clock CK2 and generates the inverted second clock CK2B and the delayed second clock CK2D based on the received second clock CK2 to provide the inverted second clock CK2B and the delayed second clock CK2D to the first to n-th flip-flops 60-1 to 60-n. In addition, in the semiconductor circuit 5 according to an exemplary embodiment, the plurality of flip-flops 60-1 to 60-n may be designed as a single sync cell to be provided as a standard cell to a design library.

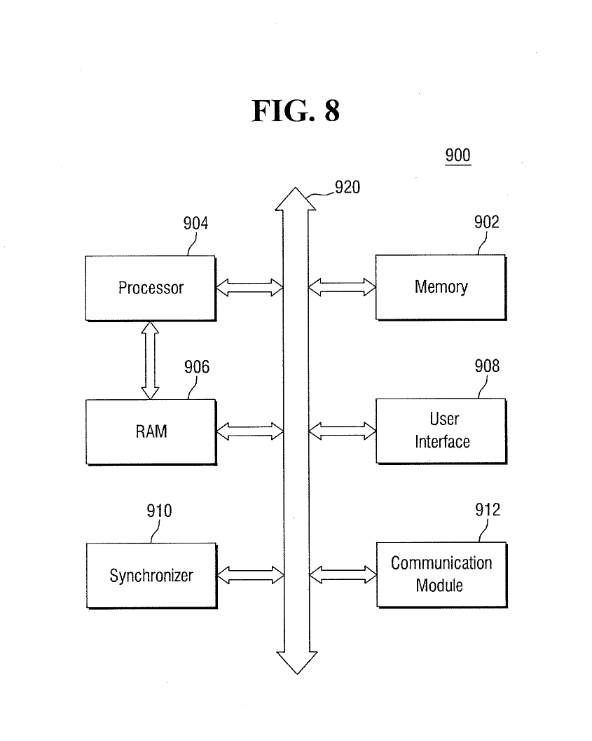

Next, an electronic system to which semiconductor circuits according to exemplary embodiments may be employed will be described with reference to FIG. 8.

FIG. 8 is a block diagram of an electronic system to which a semiconductor circuit according to exemplary embodiments may be employed.

Referring to FIG. 8, an electronic system 900 may include a memory system 902, a processor 904, a random access memory (RAM) 906, a user interface 908, a synchronizer 910, and a communication module 912.

The memory system 902, the processor 904, the RAM 906, the user interface 908, the synchronizer 910 and the communication module 912 may perform data communication with one another using a bus 920.

The processor 904 may execute a program for controlling the electronic system 900. The processor 904 may include at least one from among a microprocessor, a digital signal processor, and logic elements capable of performing functions similar to those of the above elements.

The RAM 906 may be used as an operating memory of the processor 904. For example, the RAM 906 may include a volatile memory such as a dynamic RAM (DRAM). The processor 904 and the RAM 906 may be packaged into a semiconductor device or a semiconductor package.

The user interface 908 may be used to input or output data to or from the electronic system 900. The user interface 908 may include, for example, a key pad, a key board, an image sensor, a display device.

The memory system 902 may store codes for an operation of the processor 904, data processed by the processor 904, or externally input data. The memory system 902 may include a separate controller (not shown) for driving the memory system 902, and may further include an error correction block (not shown). The error correction block may be configured to detect and correct an error of the data stored in the memory system 902 using an error correction code (ECC).

In an information processing system such as, for example, a mobile device or a desk top computer, a flash memory may be mounted as the memory system 902. For example, the memory system 902 may be configured to be applied to a solid state drive (SSD). In this case, the electronic system 900 may stably and reliably store higher capacity data in the flash memory.

In an exemplary embodiment, the memory system 902 may be integrated into a semiconductor device to provide a memory card. For example, the memory system 902 may be integrated into a semiconductor device to provide a memory card such as, for example, a personal computer memory card international association (PCMCIA) card, a compact flash (CF) card, a smart media card, a memory stick, a multimedia card (MMC) including a reduced size MMC (RS-MMC) and an MMC-micro, a secure digital (SD) card including a mini-SD, a micro-SD and a secure digital high capacity (SDHC) card, or a universal flash storage (UFS) card.

The communication module 912 may be a module for processing a communication procedure between the electronic system 900 and an external device (not shown).

The synchronizer 910 may convert data clocks to allow the aforementioned components to exchange data in a reliable manner. The semiconductor circuits 1 to 5 according to exemplary embodiments may be employed as the synchronizer 910. For example, when the processor 904 is in the first clock domain (e.g., 10 of FIG. 1) and the memory system 902 is in the second clock domain (e.g., 20 of FIG. 2), the synchronizer 910 may convert clocks of exchanged data to allow more reliable data exchange between the processor 904 and the memory system 902. In addition, when the processor 904 is in the first clock domain (e.g., 10 of FIG. 1) and the communication module 912 is in the second clock domain (e.g., 20 of FIG. 2), the synchronizer 910 may convert clocks of exchanged data to allow more reliable data exchange between the processor 904 and the communication module 912.

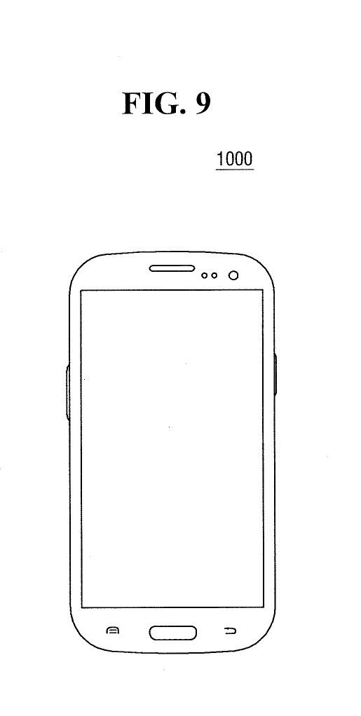

The electronic system 900 as shown in FIG. 8 may be applied to electronic controllers of various electronic devices. FIG. 9 illustrates an exemplary electronic system used for a smart phone. As shown in FIG. 9, in a case where the electronic system 900 as shown in FIG. 8 is used for a smart phone 1000, the electronic system (900 of FIG. 8) may be employed as a component of an application processor (AP) implemented in a system on chip (SoC) type.

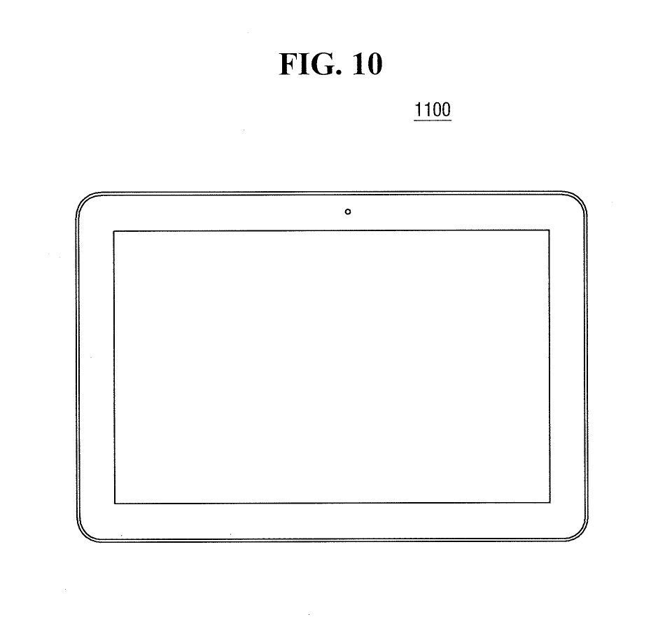

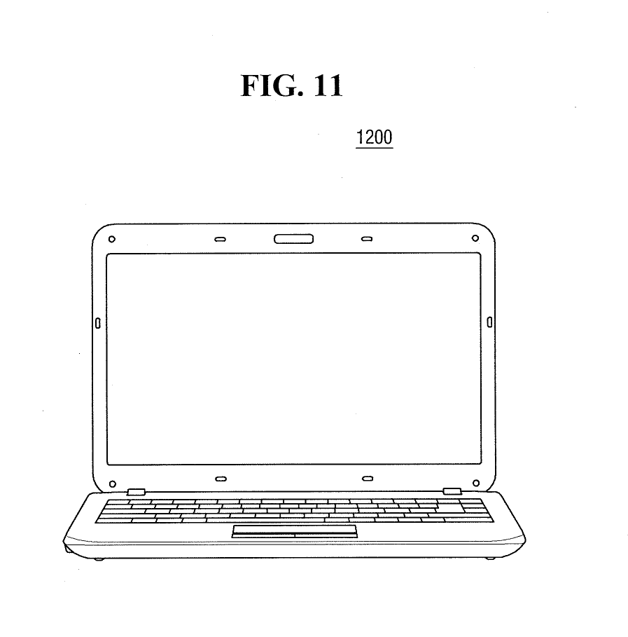

The electronic system 900 may be applied to electronic control devices of a variety of electronic devices. FIG. 10 illustrates an example in which the electronic system 900 is applied to a tablet PC, and FIG. 11 illustrates an example in which the electronic system 900 is applied to a laptop or a notebook computer.

In addition, the electronic system 900 may be applied to a personal computer (PC), a ultra mobile PC (UMPC), a workstation, a net-book, a personal digital assistant (PDA), a portable computer, a web tablet, a wireless phone, a mobile phone, an e-book, a portable multimedia player (PMP), a portable game machine, a navigation device, a black box, a digital camera, a three-dimensional (3D) television, digital audio recorder, digital audio player, digital picture recorder, digital picture player, a digital video recorder, a digital video player, a device capable of transmitting and receiving information in a radio frequency (RF) signal, a radio frequency identification (RFID) device, an electronic device included in a home network, an electronic device included in a computer network, an electronic device included in a telemetric network, or an electronic device included in a computing system.

In a case where the electronic system 900 is equipment capable of performing wireless communication, the electronic system may be used in a communication interface protocol for a communication system such as Code Division Multiple Access (CDMA), Global System for Mobile Communication (GSM), North American Digital Cellular (NADC), Time Division Multiple Access (TDMA), Extended Time Division Multiple Access (E-TDMA), Wideband Code Division Multiple Access (WCDMA), or Code Division Multiple Access 2000 (CDMA2000).

The foregoing exemplary embodiments are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. A semiconductor circuit comprising:
a first flip-flop configured to, based on input data synchronized to a first clock, output first output data synchronized to a second clock different from the first clock; and
a second flip-flop configured to, based on the first output data, output second output data synchronized to the second clock,
wherein the first and the second flip-flops share an inverted second clock and a delayed second clock and output the first and the second output data based thereon, respectively.

2. The semiconductor circuit of claim 1, wherein the inverted second clock is generated by a first inverter provided in the first flip-flop and is provided to the second flip-flop.

3. The semiconductor circuit of claim 2, wherein the delayed second clock is generated by a second inverter, provided in the first flip-flop and connected to the first inverter in series, and is provided to the second flip-flop.

4. The semiconductor circuit of claim 1, wherein the first flip-flop includes a first latch and a second latch, the first latch performs a latching operation when a level of the second clock is a first level, and the second latch performs a latching operation when the level of the second clock is a second level different from the first level.

5. The semiconductor circuit of claim 4, wherein the first level is a logical low level and the second level is a logical high level.

6. The semiconductor circuit of claim 4, wherein the second flip-flop includes a third latch and a fourth latch, the third latch performs a latching operation when the level of the second clock is the first level, and the fourth latch performs a latching operation when the level of the second clock is the second level.

7. The semiconductor circuit of claim 1, wherein the second flip-flop includes a multiplexer configured to select one of the first output data and a control signal to be input to the second flip-flop.

8. The semiconductor circuit of claim 7, wherein the control signal includes at least one from among a scan signal, a set signal, and a reset signal.

9. The semiconductor circuit of claim 1, further comprising a clock converter configured to generate the inverted second clock and the delayed second clock based on the second clock and provides the inverted second clock and the delayed second clock to the first and the second flip-flops.

10. The semiconductor circuit of claim 1, wherein the semiconductor circuit comprises a synchronizer.

11. The semiconductor circuit of claim 10, wherein the synchronizer is provided in an application processor (AP).

12. The semiconductor circuit of claim 1, further comprising a third flip-flop configured to, based on the second output data, output third output data synchronized to the second clock,
wherein the first through the third flip-flops share the inverted second clock and the delayed second clock and output the first through the third output data based thereon, respectively.

13. A method for operating a semiconductor circuit, the method comprising:
generating an inverted second clock and a delayed second clock from a second clock;
receiving input data synchronized to a first clock different from the second clock;
outputting first output data synchronized to the second clock based on the input data; and
outputting second output data synchronized to the second clock based on the first output data, wherein the outputting the first output data and the outputting the second output data are performed based on a shared inverted second clock and a shared delayed second clock.

14. The method of claim 13, wherein the generating is performed prior to the outputting the first output data.

15. The method of claim 13, wherein the outputting the first output data comprises outputting the first output data by performing a first latching operation on the input data when a level of the second clock is a first level, and performing a second latching operation on the first latched data when the level of the second clock is a second level different from the first level.

16. A semiconductor circuit comprising:
a plurality of flip-flops comprising a first through an n-th flip-flops connected to one another in series, wherein the first flip-flop outputs data synchronized to a second clock based on input data synchronized to a first clock different from the second clock, an inverted second clock, and a delayed second clock,
wherein each of a second through the n-th flip-flops outputs data synchronized to the second clock based on input data from an adjacent flip-flop, the inverted second clock, and the delayed second clock, and
wherein at least one of the inverted second clock and the delayed second clock is shared among at least a portion of the first through the n-th flip-flops.

17. The semiconductor circuit of claim 16, wherein the at least one of the inverted second clock and the delayed second clock is generated by the first flip-flop and provided to at least one of the second through the n-th flip-flops.

18. The semiconductor circuit of claim 16, further comprising a clock generator configured to provide the at least one of the inverted second clock and the delayed second clock to at least the portion of the first through the n-th flip-flops.

19. The semiconductor circuit of claim 16, wherein the semiconductor circuit comprises a synchronizer.

20. The semiconductor circuit of claim 16, wherein data output from the first through the n-th flip-flops maintain an original state of the input data of the first flip-flop.
